(19) United States
(12) Patent Application Publication
(10) Pub. No.: US 2010/0187584 A1
(43) Pub. Date: Jul. 29, 2010

(54) SEMICONDUCTOR DEVICE AND METHOD FOR FABRICATING THE SAME

(76) Inventor: Takayuki MATSUDA, Kyoto (JP)

Correspondence Address: MCDERMOTT WILL & EMERY LLP, 600 13TH STREET, NW, WASHINGTON, DC, 20005-3096, US

(21) Appl. No.: 12/628,439

(22) Filed: Dec. 1, 2009

(30) Foreign Application Priority Data
Jan. 27, 2009 (JP) 2009-015356

(51) Int. Cl. H01L 27/108; H01L 21/8242

(52) U.S. Cl. 257/295; 438/3; 257/E27.084; 257/E21.646

(57) ABSTRACT

A semiconductor device includes an interlayer insulating film having an opening, an adhesion layer formed on at least a side wall of the opening, a lower electrode formed on a bottom surface of the opening and at least a side surface of the adhesion layer, a capacitor insulating film made of a ferroelectric formed on the lower electrode, and an upper electrode formed on the capacitor insulating film. The lower electrode, the capacitor insulating film and the upper electrode constitute a capacitor, and the capacitor has a cross-section having a recessed shape in the opening. The lower electrode has a protruding portion protruding from the opening. The capacitor insulating film is formed, covering at least the protruding portion of the lower electrode, of the lower electrode and the adhesion layer. The upper electrode is formed, covering the capacitor insulating film formed on the protruding portion.

### CROSS-REFERENCE TO RELATED APPLICATION

This application claims priority to Japanese Patent Application No. 2009-15356 filed on Jan. 27, 2009, the disclosure of which including the specification, the drawings, and the claims is hereby incorporated by reference in its entirety.

### BACKGROUND

The present disclosure relates to semiconductor devices including a ferroelectric film or a high-k film as a capacitor insulating film, and methods for fabricating the semiconductor devices. More particularly, the present disclosure relates to memory cells having a three-dimensional structure.

In recent years, as electronic money and the like have progressed, there has been an increasing demand for non-volatile memory devices capable of performing read and write operations with a low operating voltage and a high speed. As non-volatile memory devices having such characteristics, non-volatile memory devices including a high-k film or a ferroelectric film as a capacitor insulating film have been employed. As the devices have been employed in a wider variety of applications in recent years, a larger storage capacity per unit area has been essentially required. Therefore, in order to increase an area contributing to formation of an amount of charge without increasing the projected area of a memory cell, three-dimensional cells are increasingly developed instead of conventional planar cells. A conventional three-dimensional cell and its fabricating method are disclosed in, for example, Japanese Patent Laid-Open Publication No. 2001-210802.

However, due to further progress in miniaturization, the amount of accumulated charge is becoming insufficient even in the conventional three-dimensional cell structure. Therefore, a structure for attaining a larger charge capacity in the same projected area is disclosed in, for example, Japanese Patent Laid-Open Publication No. 2002-217388. As shown in FIGS. 7A and 7B, in the structure, a portion of an interlayer insulating film 16 which is formed, surrounding a three-dimensional cell, is etched to expose a portion of outer side surfaces of a lower electrode 26 of the three-dimensional cell, whereby both surfaces of the lower electrode 26 can contribute to an increase in charge capacity.

### SUMMARY

On the other hand, when a ferroelectric film is employed as a capacitor insulating film, a Rapid Thermal Oxidation (RTO) process which is a thermal process of crystallizing the ferroelectric film in oxygen atmosphere is essentially required. In a three-dimensional cell shown in FIG. 7B, when a silicon oxide film, which is commonly used as a material for interlayer insulating films, is employed, the silicon oxide film and a noble metal electrode which is commonly used in a ferroelectric memory device have largely different coefficients of linear expansion in response to changes in temperature as shown in FIG. 8.

Thus, as shown in FIG. 7C, the interlayer insulating film 16 made of silicon oxide and the lower electrode 26 made of a noble metal are peeled apart, leading to deformation of the lower electrode 26, i.e., a non-defective memory cell cannot be formed, which is a problem.

Therefore, the present disclosure has been made in view of the aforementioned problem. It is an object of the present disclosure to provide a three-dimensional cell having a structure in which a portion of an interlayer insulating film which is formed, surrounding the three-dimensional cell, is etched to expose a portion of outer side surfaces of a lower electrode of the three-dimensional cell, whereby both surfaces of the lower electrode can contribute to an increase in charge capacity, and in which a metal electrode included in the lower electrode is prevented from being deformed, to allow the three-dimensional cell to have a non-defective shape, thereby providing a semiconductor device in which the charge capacity can be increased without changing the projected area.

To solve the aforementioned problem, the present disclosure provides a semiconductor device having a structure in which an adhesion layer is provided between an interlayer insulating film and a lower electrode.

Specifically, a first semiconductor device according to the present disclosure includes an interlayer insulating film formed on a semiconductor substrate and having an opening, an adhesion layer formed on at least a side wall of the opening, a first lower electrode formed on a bottom surface of the opening and at least a side surface of the adhesion layer, a capacitor insulating film made of a ferroelectric or high-k material formed on the first lower electrode, and an upper electrode formed on the capacitor insulating film. The first lower electrode, the capacitor insulating film and the upper electrode constitute a capacitor, and the capacitor has a cross-section having a recessed shape in the opening formed in the interlayer insulating film. The first lower electrode has a protruding portion protruding from the opening. The capacitor insulating film is formed, covering at least the protruding portion of the first lower electrode, of the lower electrode and the adhesion layer. The upper electrode is formed, covering the capacitor insulating film formed on the protruding portion.

According to the first semiconductor device of the present disclosure, the adhesion layer formed between the interlayer insulating film and the first lower electrode prevents the interlayer insulating film and the first lower electrode from being peeled apart even if an RTO process is conducted, whereby a non-defective three-dimensional cell shape can be maintained.

In the first semiconductor device of the present disclosure, the adhesion layer may be formed, protruding from the opening. The first lower electrode may be formed on the side surface of the adhesion layer. The capacitor insulating film may be formed, covering protruding portions protruding from the opening of the first lower electrode and the adhesion layer.

Also, in the first semiconductor device of the present disclosure, the adhesion layer may be formed only on the side wall of the opening. The protruding portion of the first lower electrode may protrude from an upper end of the adhesion layer. The capacitor insulating film may be formed, directly covering the protruding portion of the first lower electrode.

A second semiconductor device according to the present disclosure includes an interlayer insulating film formed on a semiconductor substrate and having an opening, an adhesion layer formed on at least a side wall of the opening and having a protruding portion protruding above the interlayer insulating film, a first lower electrode formed on a bottom surface of the opening and a side surface of the adhesion layer, a second lower electrode formed on the first lower electrode, a capacitor insulating film made of a ferroelectric or high-k material formed on the second lower electrode, and an upper electrode formed on the capacitor insulating film. The first lower electrode, the capacitor insulating film and the upper electrode constitute a capacitor, and the capacitor has a cross-section having a recessed shape in the opening formed in the interlayer insulating film. The second lower electrode is formed, extending from over the first lower electrode to over an outer side surface of the protruding portion of the adhesive layer. The capacitor insulating film is formed, covering the second lower electrode formed at the protruding portion. The upper electrode is formed, covering the capacitor insulating film formed at the protruding portion.

According to the second semiconductor device of the present disclosure, the adhesion layer formed between the interlayer insulating film and the first lower electrode prevents the interlayer insulating film and the first lower electrode from being peeled apart even if an RTO process is conducted, whereby a non-defective three-dimensional cell shape can be maintained.

The first or second semiconductor device of the present disclosure may further include an oxygen barrier film formed between the bottom surface of the opening in the interlayer insulating film and the first lower electrode.

The first or second semiconductor device of the present disclosure may further include a contact plug formed in a lower portion of the opening in the interlayer insulating film and electrically connected to the first lower electrode.

In the first or second semiconductor device of the present disclosure, a length of the protruding portion of the first lower electrode may be smaller than or equal to one third of the sum of the length of the protruding portion of the first lower electrode and a length of a portion facing the side wall of the opening of the interlayer insulating film.

In the first or second semiconductor device of the present disclosure, the adhesion layer may be made of one of titanium oxide, titanium nitride, titanium aluminum nitride, titanium aluminum oxynitride, iridium oxide, iridium, ruthenium oxide, and ruthenium, or a multilayer film including two or more thereof.

In the first or second semiconductor device of the present disclosure, the first lower electrode and the upper electrode may each be made of one of platinum, iridium, ruthenium, gold, silver, palladium, an oxide of rhodium or osmium, iridium oxide, ruthenium oxide, iron oxide, and silver oxide, or a multilayer film including two or more thereof.

In the second semiconductor device of the present disclosure, the second lower electrode may be made of one of platinum, iridium, ruthenium, gold, silver, palladium, an oxide of rhodium or osmium, iridium oxide, ruthenium oxide, iron oxide, and silver oxide, or a multilayer film including two or more thereof.

In the first or second semiconductor device of the present disclosure, the ferroelectric material may be a compound having a perovskite structure whose general formula is represented by ABO₃, where A and B are different elements.

In this case, the element A may be at least one selected from the group consisting of lead, barium, strontium, calcium, lanthanum, lithium, sodium, potassium, magnesium, and bismuth, and the element B may be at least one selected from the group consisting of titanium, zirconium, niobium, tantalum, tungsten, iron, nickel, scandium, cobalt, hafnium, magnesium, and molybdenum.

A method for fabricating a semiconductor device according to the present disclosure includes the steps of (a) forming a first interlayer insulating film on a semiconductor substrate, (b) forming a contact plug in the first interlayer insulating film, the contact plug being connected to the semiconductor substrate, (c) forming a second interlayer insulating film on the first interlayer insulating film, the second interlayer insulating film covering the contact plug, (d) forming an opening in the second interlayer insulating film, the opening exposing the contact plug, (e) forming an adhesion layer on at least a side wall of the opening, (f) forming a first lower electrode on a bottom surface of the opening and a side surface of the adhesion layer, (g) removing an upper portion surrounding the opening of the second interlayer insulating film to allow a portion of the adhesion layer and a portion of the first lower electrode to protrude above the second interlayer insulating film, (h) forming a second lower electrode extending from along the first lower electrode in the opening to over an outer side surface of the portion protruding above the second interlayer insulating film of the adhesion layer, (i) forming a capacitor insulating film made of a ferroelectric or high-k material, the capacitor insulating film extending from along the second lower electrode in the opening to over an outer side surface of the second lower electrode at the portion protruding above the second interlayer insulating film of the adhesion layer, (j) forming an upper electrode extending from along the capacitor insulating film in the opening to over an outer side surface of the capacitor insulating film at the portion protruding above the second interlayer insulating film of the adhesion layer, (k) forming a third interlayer insulating film on the second interlayer insulating film including the upper electrode, and (l) after step (k), subjecting the semiconductor substrate to a thermal process under oxidation atmosphere to crystallize the capacitor insulating film. The first lower electrode, the second lower electrode, the capacitor insulating film, and the upper electrode constitute a capacitor. The capacitor has a cross-section having a recessed shape in the opening formed in the second interlayer insulating film.

According to the semiconductor device fabricating method of the present disclosure, the adhesion layer formed between the interlayer insulating film and the first lower electrode prevents the interlayer insulating film and the first lower electrode from being peeled apart even if an RTO process is conducted, whereby a non-defective three-dimensional cell shape can be maintained.

The semiconductor device fabricating method of the present disclosure may further include the step of (m) between steps (b) and (c), forming an oxygen barrier film covering the contact plug. In step (d), the oxygen barrier film may be exposed instead of the contact plug.

In the semiconductor device fabricating method of the present disclosure, in step (g), the upper portion surrounding the opening of the second interlayer insulating film may be removed so that a length of the portion protruding above the second interlayer insulating film of the adhesion layer and the first lower electrode is smaller than or equal to one third of the sum of the length of the portion protruding above the second interlayer insulating film of the adhesion layer and the first lower electrode and a length of a portion facing the side wall of the opening of the second interlayer insulating film.

In the semiconductor device fabricating method of the present disclosure, the adhesion layer may be made of one of titanium oxide, titanium nitride, titanium aluminum nitride, titanium aluminum oxynitride, iridium oxide, iridium, ruthenium oxide, and ruthenium, or a multilayer film including two or more thereof.

In the semiconductor device fabricating method of the present disclosure, the first and second lower electrodes and the upper electrode may each be made of one of platinum, iridium, ruthenium, gold, silver, palladium, an oxide of rhodium or osmium, iridium oxide, ruthenium oxide, iron oxide, and silver oxide, or a multilayer film including two or more thereof.

In the semiconductor device fabricating method of the present disclosure, the ferroelectric material may be a compound having a perovskite structure whose general formula is represented by ABO₃, where A and B are different elements.

In this case, the element A may be at least one selected from the group consisting of lead, barium, strontium, calcium, lanthanum, lithium, sodium, potassium, magnesium, and bismuth, and the element B may be at least one selected from the group consisting of titanium, zirconium, niobium, tantalum, tungsten, iron, nickel, scandium, cobalt, hafnium, magnesium, and molybdenum.

As described above, according to the semiconductor device of the present disclosure and its fabricating method, the adhesion layer formed between the interlayer insulating film and the first lower electrode prevents the interlayer insulating film and the first lower electrode from being peeled apart even if an RTO process is conducted, whereby a non-defective three-dimensional cell shape can be maintained. As a result, a semiconductor device having a high yield and high reliability can be obtained.

### BRIEF DESCRIPTION OF THE DRAWINGS

FIG. 1 is a cross-sectional view showing a semiconductor device according to a first illustrative embodiment.

FIG. 2 is a cross-sectional view showing a semiconductor device according to a second illustrative embodiment.

FIG. 3 is a cross-sectional view showing a semiconductor device according to a third illustrative embodiment.

FIGS. 4A-4C are cross-sectional views showing a method for fabricating the semiconductor device of the third illustrative embodiment in the order in which the semiconductor device is fabricated.

FIGS. 5A and 5B are cross-sectional views showing a method for fabricating the semiconductor device of the third illustrative embodiment in the order in which the semiconductor device is fabricated.

FIGS. 6A-6C are cross-sectional views of semiconductor devices according to the present disclosure including second interlayer insulating films having different heights.

FIGS. 7A-7C are cross-sectional view showing a semiconductor device according to a conventional example and its fabricating method.

FIG. 8 is a graph showing the temperature dependence of the coefficients of expansion of materials used in the illustrative embodiments and the conventional example.

### DETAILED DESCRIPTION

### First Illustrative Embodiment

A semiconductor device according to a first illustrative embodiment will be described with reference to FIG. 1. FIG. 1 shows a cross-sectional structure of the semiconductor device of the first illustrative embodiment.

As shown in FIG. 1, a first interlayer insulating film 40 made of silicon oxide having a thickness of 600 nm is formed on a semiconductor substrate 10 which has an isolation region 20 and a silicide region 30. A hydrogen barrier film 100 made of silicon nitride having a thickness of 50 nm to 150 nm is formed on the first interlayer insulating film 40 so as to prevent a deterioration in characteristics of a capacitor which is caused by reduction of a ferroelectric film due to hydrogen entering from the first interlayer insulating film 40. Also, contact holes are formed which penetrate through the hydrogen barrier film 100 and the first interlayer insulating film 40 to expose the silicide region 30. In each of the contact holes, a contact plug 120 is formed which is made of an adhesion layer made of titanium (Ti)/titanium nitride (TiN) and tungsten which is deposited by W (tungsten)-Chemical Vapor Deposition (W-CVD). A conductive oxygen barrier film 140 which is a multilayer film made of, for example, platinum (Pt)/iridium oxide (IrO₂)/iridium (Ir)/titanium aluminum nitride (TiAlN), is formed on each contact plug 120, covering the contact plug 120. Here, it is assumed that the multilayer film included in the oxygen barrier film 140 has a film thickness of 100 nm to 300 nm. Also, a second interlayer insulating film 160 is formed to fill a space between the adjacent oxygen barrier films 140. A hole (opening) 180 for forming a three-dimensional memory cell is formed on the oxygen barrier film 140 on each contact plug 120.

An adhesion layer 240 having a thickness of 20 nm to 100 nm is formed on a side wall in the hole 180 of the second interlayer insulating film 160 so as to improve adhesiveness between the second interlayer insulating film 160 and a lower electrode 260 which is subsequently formed, in each structure which subsequently forms a memory cell. Although a typical semiconductor device includes a number of cells, only a single cell will be discussed below unless explicitly specified using the term “in each structure” or “in each memory cell.” Here, the adhesion layer 240 is formed, protruding above the hole 180. The adhesion layer 240 is preferably made of one of titanium oxide, titanium nitride, titanium aluminum nitride, titanium aluminum oxynitride, iridium oxide, iridium, ruthenium oxide, and ruthenium, or a multilayer film including two or more thereof.

The lower electrode 260 made of a conductive film is formed along the adhesion layer 240 and the oxygen barrier film 140 in the hole 180. The lower electrode 260 has a protruding portion 260a which protrudes above the hole 180 as with the adhesion layer 240. Here, it is assumed that the conductive film is primarily made of a noble metal (e.g., platinum (Pt)) and having a film thickness of, for example, 20 nm to 150 nm. Also, the protruding portion 260a preferably has a length which is smaller than or equal to one third of the sum of the length of the protruding portion 260a of the lower electrode 260 and a length of a portion facing the side wall of the hole 180 of the second interlayer insulating film 160.

A ferroelectric film 360 made of, for example, Bi₄Ti₃O₁₂ (abbreviated as BiT) having a thickness of 30 nm to 100 nm is formed on the lower electrode 260. Here, the ferroelectric film 360 is formed, covering upper portions of the adhesion layer 240 and the lower electrode 260, i.e., an outer portion of the protruding portion 260a protruding outward. The ferroelectric film 360 may be made of a compound having a perovskite structure whose general formula is represented by ABO₃, where A and B are different elements, in addition to BiT. Also, in this case, the element A is preferably at least one selected from the group consisting of lead, barium, strontium, calcium, lanthanum, lithium, sodium, potassium, magnesium, and bismuth, and the element B is preferably at least one selected from the group consisting of titanium, zirconium, niobium, tantalum, tungsten, iron, nickel, scandium, cobalt, hafnium, magnesium, and molybdenum.

An upper electrode 340 which is primarily made of a noble metal (e.g., platinum (Pt)) and having a thickness of, for example, 20 nm to 150 nm is formed on the ferroelectric film 360. Here, the upper electrode 340 is formed, covering the ferroelectric film 360 which is formed, covering the adhesion layer 240 and the protruding portion 260a of the lower electrode 260. The lower electrode 260 and the upper electrode 340 may each be made of one of iridium, ruthenium, gold, silver, palladium, an oxide of rhodium or osmium, iridium oxide, ruthenium oxide, and silver oxide, or a multilayer film including two or more thereof, in addition to platinum. Moreover, iron oxide may be used.

A third interlayer insulating film 380 is formed on the second interlayer insulating film 160 and the upper electrode 340.

As described above, according to the semiconductor device of the first illustrative embodiment, the adhesion layer 240 is provided between the second interlayer insulating film 160 and the lower electrode 260, and therefore, even if the RTO process essentially required for non-volatile memory devices including a ferroelectric film is conducted, the lower electrode 260 is not peeled from the second interlayer insulating film 160. Therefore, the lower electrode 260 of a three-dimensional cell, of which a portion of an upper portion is exposed, does not suffer from tensile stress due to the peeling, and therefore, a non-defective three-dimensional cell can be formed. As a result, a semiconductor device having a high yield and high reliability can be obtained.

### Second Illustrative Embodiment

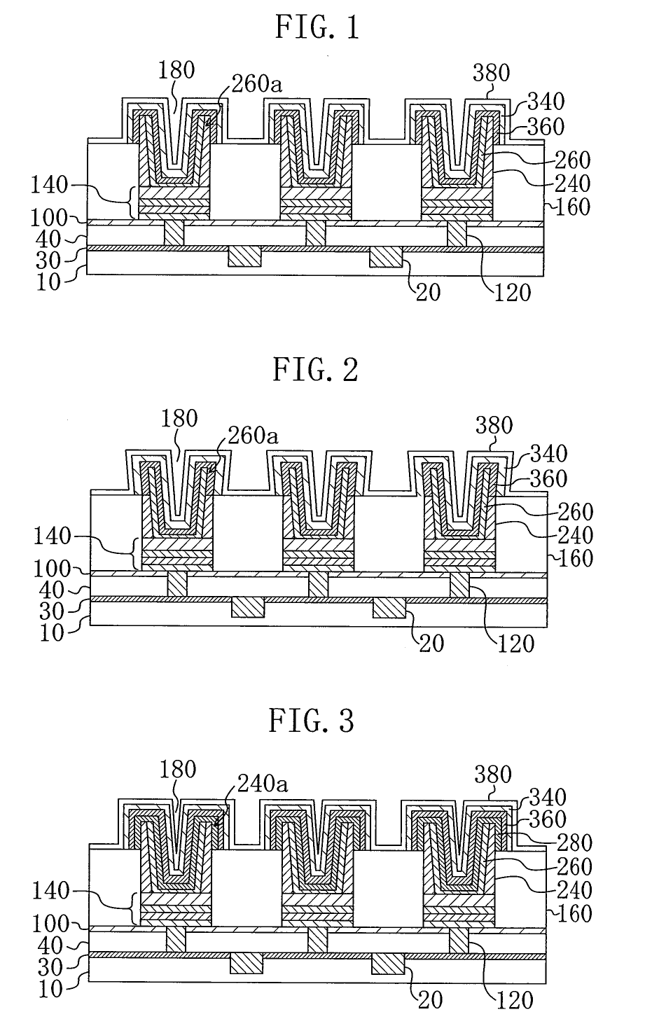

A semiconductor device according to a second illustrative embodiment will be described hereinafter with reference to FIG. 2. FIG. 2 shows a cross-sectional structure of the semiconductor device of the second illustrative embodiment.

In FIG. 2, the same parts as those of FIG. 1 are indicated by the same reference characters and will not be described. The second illustrative embodiment is different from the first illustrative embodiment as follows.

As shown in FIG. 2, an adhesion layer 240 having a thickness of 20 nm to 100 nm is formed on a side wall in a hole 180 of a second interlayer insulating film 160 so as to improve adhesiveness between the second interlayer insulating film 160 and a lower electrode 260 which is subsequently formed. Here, the adhesion layer 240 is formed only on the side wall of the second interlayer insulating film 160 in a manner which prevents the adhesion layer 240 to protrude above the hole 180. The adhesion layer 240 is preferably made of one of titanium oxide, titanium nitride, titanium aluminum nitride, titanium aluminum oxynitride, iridium oxide, iridium, ruthenium oxide, and ruthenium, or a multilayer film including two or more thereof.

The lower electrode 260, which is made of a conductive film, is formed along the adhesion layer 240 and an oxygen barrier film 140 in the hole 180. The lower electrode 260 is not only provided on a side surface of the adhesion layer 240, but also has a protruding portion 260a which protrudes above the hole 180. Here, it is assumed that the conductive film is primarily made of a noble metal (e.g., platinum (Pt)) and having a film thickness of, for example, 20 nm to 150 nm. Also, the protruding portion 260a preferably has a length which is smaller than or equal to one third of the sum of the length of the protruding portion 260a protruding above the second interlayer insulating film 160 of the lower electrode 260 and a length of a portion facing a side wall of the hole 180 of the second interlayer insulating film 160.

A ferroelectric film 360 made of, for example, BiT having a thickness of 30 nm to 100 nm is formed on the lower electrode 260. Here, the ferroelectric film 360 is formed, covering an upper portion of the lower electrode 260, i.e., an outer portion of the protruding portion 260a protruding outward. The ferroelectric film 360 may be made of a compound having a perovskite structure whose general formula is represented by ABO₃, where A and B are different elements, in addition to BiT. Also, in this case, the element A is preferably at least one selected from the group consisting of lead, barium, strontium, calcium, lanthanum, lithium, sodium, potassium, magnesium, and bismuth, and the element B is preferably at least one selected from the group consisting of titanium, zirconium, niobium, tantalum, tungsten, iron, nickel, scandium, cobalt, hafnium, magnesium, and molybdenum.

An upper electrode 340 which is primarily made of a noble metal (e.g., platinum (Pt)) and having a thickness of, for example, 20 nm to 150 nm is formed on the ferroelectric film 360. Here, the upper electrode 340 is formed, covering the ferroelectric film 360 which is formed, covering the protruding portion 260a of the lower electrode 260. The lower electrode 260 and the upper electrode 340 may each be made of one of iridium, ruthenium, gold, silver, palladium, an oxide of rhodium or osmium, iridium oxide, ruthenium oxide, and silver oxide, or a multilayer film including two or more thereof, in addition to platinum. Moreover, iron oxide may be used.

A third interlayer insulating film 380 is formed on the second interlayer insulating film 160 and the upper electrode 340.

As described above, according to the semiconductor device of the second illustrative embodiment, the adhesion layer 240 is provided between the second interlayer insulating film 160 and the lower electrode 260, and therefore, even if the RTO process essentially required for non-volatile memory devices including a ferroelectric film is conducted, the lower electrode 260 is not peeled from the second interlayer insulating film 160. Therefore, the lower electrode 260 of a three-dimensional cell, of which a portion of an upper portion is exposed, does not suffer from tensile stress due to the peeling, and therefore, a non-defective three-dimensional cell can be formed. As a result, a semiconductor device having a high yield and high reliability can be obtained. Moreover, as is different from the first illustrative embodiment, the adhesion layer 240 is not interposed between the ferroelectric film 360 and the lower electrode 260, and therefore, it is expected that an effect similar to when the ferroelectric film 360 has a smaller film thickness is exhibited. If the adhesion layer 240 has the same film thickness as that of the ferroelectric film 360, then when both surfaces of a portion of the lower electrode 260 are allowed to contribute to formation of a capacitor, the effect of increasing the charge capacity is doubled as compared to the first illustrative embodiment in which the adhesion layer 240 is interposed.

### Third Illustrative Embodiment

A semiconductor device according to a third illustrative embodiment will be described hereinafter with reference to FIG. 3. FIG. 3 shows a cross-sectional structure of the semiconductor device of the third illustrative embodiment.

In FIG. 3, the same parts as those of FIG. 1 are indicated by the same reference characters and will not be described. The third illustrative embodiment is different from the first illustrative embodiment as follows.

As shown in FIG. 3, a second lower electrode 280 made of, for example, platinum is formed on a first lower electrode 260. Here, the second lower electrode 280 is formed, covering upper portions of an adhesion layer 240 and the first lower electrode 260, i.e., an outer portion of a protruding portion 240a protruding outward.

A ferroelectric film 360 made of, for example, BiT having a thickness of 30 nm to 100 nm is formed on the second lower electrode 280. Here, the ferroelectric film 360 is formed, covering the second lower electrode 280 which is formed, covering the protruding portion 240a of the adhesive layer 240 and the first lower electrode 260. The ferroelectric film 360 may be made of a compound having a perovskite structure whose general formula is represented by ABO₃, where A and B are different elements, in addition to BiT. Also, in this case, the element A is preferably at least one selected from the group consisting of lead, barium, strontium, calcium, lanthanum, lithium, sodium, potassium, magnesium, and bismuth, and the element B is preferably at least one selected from the group consisting of titanium, zirconium, niobium, tantalum, tungsten, iron, nickel, scandium, cobalt, hafnium, magnesium, and molybdenum.

An upper electrode 340 which is primarily made of a noble metal (e.g., platinum (Pt)) and having a thickness of, for example, 20 nm to 150 nm is formed on the ferroelectric film 360. Here, the upper electrode 340 is formed, covering the ferroelectric film 360 which is formed, covering the second lower electrode 280 which is formed, covering the protruding portion 240a of the adhesive layer 240 and the first lower electrode 260. The lower electrode 260, the second lower electrode 280 and the upper electrode 340 may each be made of one of iridium, ruthenium, gold, silver, palladium, an oxide of rhodium or osmium, iridium oxide, ruthenium oxide, and silver oxide, or a multilayer film including two or more thereof, in addition to platinum. Moreover, iron oxide may be used.

As described above, according to the semiconductor device of the third illustrative embodiment, the adhesion layer 240 is provided between the second interlayer insulating film 160 and the first lower electrode 260, and therefore, even if the RTO process essentially required for non-volatile memory devices including a ferroelectric film is conducted, the first lower electrode 260 is not peeled from the second interlayer insulating film 160. Therefore, the first lower electrode 260 and the second lower electrode 280 of a three-dimensional cell, of which portions of upper portions are exposed, do not suffer from tensile stress due to the peeling, and therefore, a non-defective three-dimensional cell can be formed. As a result, a semiconductor device having a high yield and high reliability and its fabricating method can be provided.

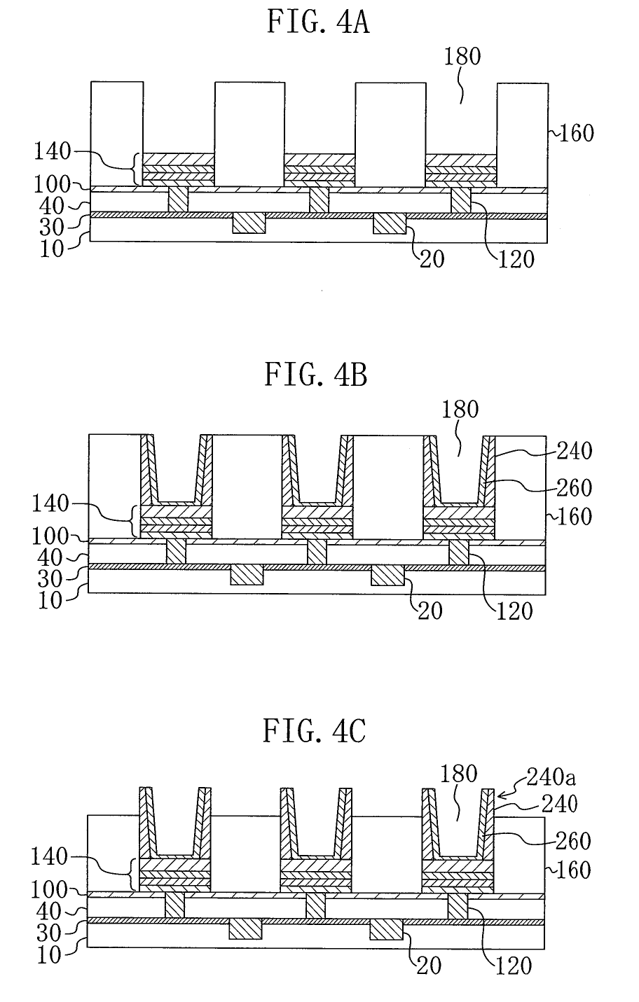

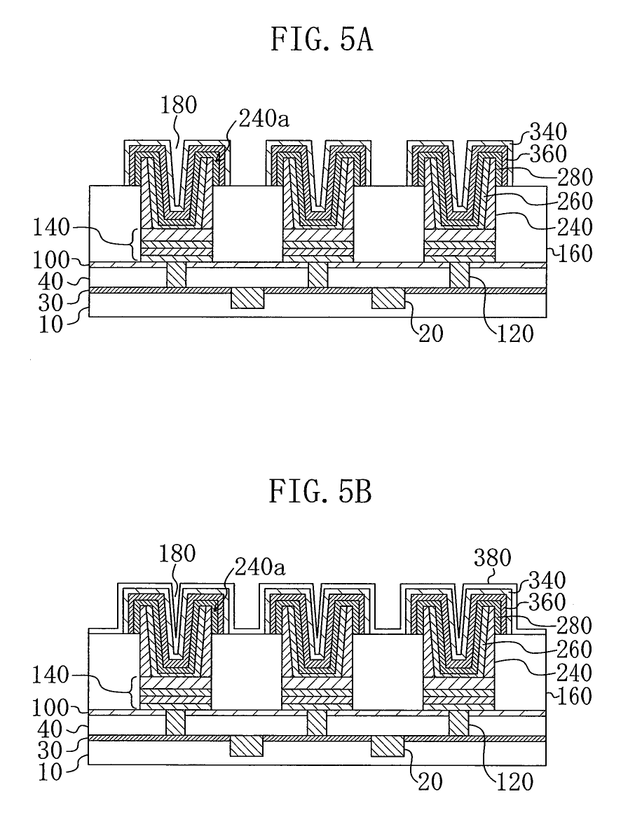

Next, a method for fabricating the semiconductor device of the third illustrative embodiment will be described with reference to FIGS. 4A-4C and FIGS. 5A and 5B.

Initially, as shown in FIG. 4A, a first interlayer insulating film 40 made of silicon oxide having a film thickness of 600 nm is deposited on a semiconductor substrate 10 having an isolation region 20 and a silicide region 30, and an upper surface of the first interlayer insulating film 40 is planarized by Chemical Mechanical Polishing (CMP). Thereafter, a hydrogen barrier film 100 made of silicon nitride having a thickness of 50 nm to 150 nm is formed on the first interlayer insulating film 40 so as to prevent a deterioration in characteristics of a capacitor which is caused by reduction of a ferroelectric film due to hydrogen entering from the first interlayer insulating film 40. Thereafter, a plurality of contact holes are formed by lithography and dry etching, which penetrate through the hydrogen barrier film 100 and the first interlayer insulating film 40 to expose the silicide region 30. Thereafter, each contact hole is filled with a Ti/TiN adhesion layer and W-CVD, and the Ti/TiN adhesion layer and W-CVD formed on the hydrogen barrier film 100 are then removed by CMP, whereby a plurality of contact plugs 120 are formed.

Next, a multilayer film made of, for example, Pt/IrO₂/Ir/TiAlN is deposited, covering each contact plug 120, and is then subjected to lithography and dry etching to form a conductive oxygen barrier film 140 in a region covering each contact plug 120. Here, it is assumed that the oxygen barrier film 140 which is a multilayer film has a film thickness of 100 nm to 300 nm. Thereafter, a second interlayer insulating film 160 having a film thickness of 1000 nm is deposited on the semiconductor substrate 10, filling a space between portions on adjacent contact plugs of the oxygen barrier film 140. Thereafter, a surface of the second interlayer insulating film 160 is planarized by CMP.

Next, holes 180 which expose the oxygen barrier film 140 and are used to form three-dimensional memory cells are formed in desired regions on the oxygen barrier film 140 by lithography and dry etching.

Next, as shown in FIG. 4B, an adhesion layer 240 having a thickness of 20 nm to 100 nm is formed, extending along an inner surface of each hole 180 and covering the second interlayer insulating film 160, so as to improve adhesiveness between the second interlayer insulating film 160 and a first lower electrode 260 which is subsequently formed. Thereafter, a resist film is applied on an entire surface of the semiconductor substrate 10, and total etch back is performed by dry etching under a condition that the etching selectivity ratio of the applied resist film and the adhesion layer 240 is close to 1:1, thereby removing the adhesion layer 240 deposited on regions other than an upper portion of the inner side wall of each hole 180, leaving the adhesion layer 240 only on the inner side wall of each hole 180.

Next, a conductive film which is to form a first lower electrode 260 is deposited, extending along the adhesion layer 240 and the oxygen barrier film 140 in each hole 180 and covering an upper surface of the second interlayer insulating film 160. Here, it is assumed that the conductive film is primarily made of a noble metal (e.g., platinum (Pt)) and has a film thickness of, for example, 20 nm to 150 nm. Thereafter, the conductive film on the second interlayer insulating film 160 is removed by, for example, CMP to form the first lower electrode 260 which covers a bottom surface and a side surface of each hole 180.

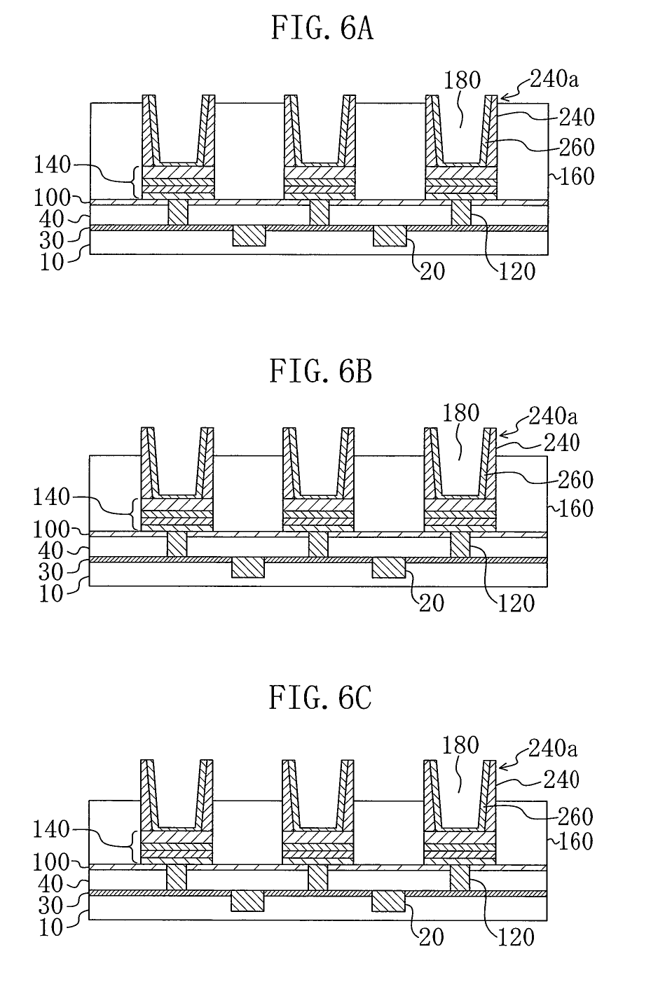

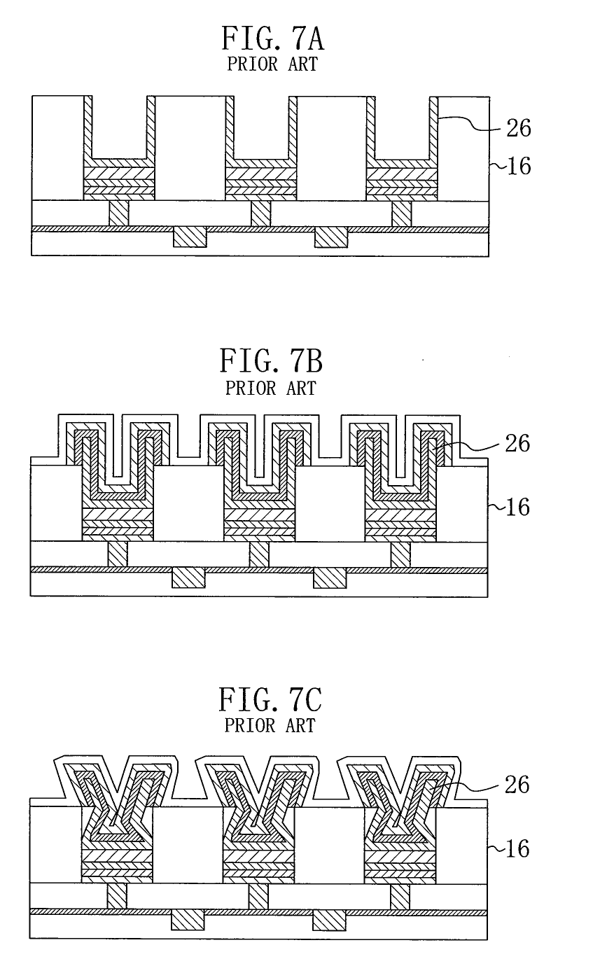

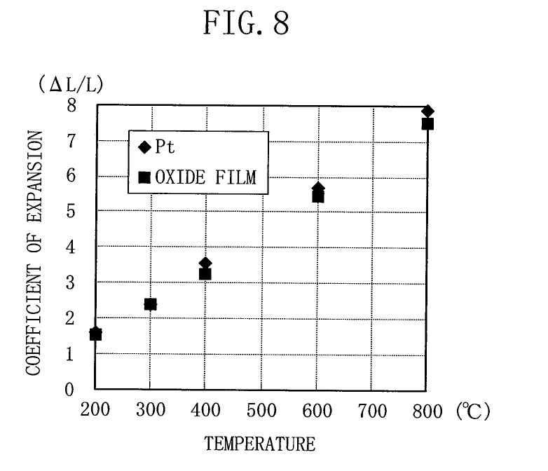

Next, as shown in FIG. 4C, an upper portion surrounding each hole 180 of the second interlayer insulating film 160 is removed to expose upper portions protruding outward of the adhesion layer 240 and the first lower electrode 260, thereby forming the protruding portion 240a. In this case, as shown in FIG. 6A, when both surfaces of a second lower electrode 280 which is subsequently formed are allowed to contribute to formation of a capacitor, then if the second interlayer insulating film 160 is removed in a film thickness corresponding to one tenth of a height of a concave portion of a three-dimensional memory cell, a surface area of the three-dimensional cell which contributes to an increase in charge capacity is increased by 10%, assuming that the concave portion of the three-dimensional cell has a diameter of 300 nm and a height of 600 nm. Also, as shown in FIG. 6B, if the second interlayer insulating film 160 is removed in a film thickness corresponding to one third of the height of the concave portion of the three-dimensional memory cell, the surface area of the three-dimensional cell which contributes to an increase in charge capacity is increased by 30%. Moreover, as shown in FIG. 6C, if the second interlayer insulating film 160 is removed in a film thickness corresponding to one second of the height of the concave portion of the three-dimensional memory cell, the surface area of the three-dimensional cell which contributes to an increase in charge capacity is increased by 44%. The aforementioned advantage can be obtained without increasing the projected area (the increase of the projected area is accompanied by a change in layout).

Note that, if the hole 180 has a diameter of as small as 1 μm or less, the first lower electrode 260 needs to be thinner. Therefore, it is desirable that the amount in which the second interlayer insulating film 160 is removed be smaller than or equal to about one third of the height of the hole 180.

Next, as shown in FIG. 5A, a layer which is primarily made of a noble metal (e.g., platinum (Pt)) and having a thickness of, for example, 20 nm to 150 nm (subsequently forms the second lower electrode 280) is deposited on the multilayer structure on the semiconductor substrate 10. Thereafter, a layer made of, for example, BiT having a 30 nm to 100 nm (subsequently forms the ferroelectric film 360) is deposited. Thereafter, moreover, a layer which is primarily made of a noble metal (e.g., platinum (Pt)) and having a thickness of, for example, 20 nm to 150 nm (subsequently forms the upper electrode 340) is deposited.

Next, a desired pattern is formed by lithography, and unnecessary portions of the ferroelectric film 360 and the upper electrode 340 are then removed by dry etching, thereby forming the ferroelectric film 360 and the upper electrode 340 extending from over the second lower electrode 280 formed in each hole 180 to over upper portions of the adhesion layer 240 and the first lower electrode 260, i.e., the second lower electrode 280 formed on outer side surfaces of the protruding portion 240a protruding outward. Thus, each three-dimensional memory cell is completed.

Next, as shown in FIG. 5B, a third interlayer insulating film 380 having a thickness of 50 nm to 300 nm is deposited on each memory cell. Thereafter, the ferroelectric film 360 is crystallized by the RTO process, thereby causing the ferroelectric film 360 to exhibit a ferroelectric characteristic.

As described above, according to the method for fabricating the semiconductor device of the third illustrative embodiment, the adhesion layer 240 is provided between the second interlayer insulating film 160 and the first lower electrode 260, and therefore, even if the RTO process essentially required for non-volatile memory devices including a ferroelectric film is conducted, the first lower electrode 260 is not peeled from the second interlayer insulating film 160. Therefore, the first lower electrode 260 and the second lower electrode 280 of a three-dimensional cell, of which portions of upper portions are exposed, do not suffer from tensile stress due to the peeling, and therefore, a three-dimensional cell having a desired shape can be formed. As a result, a semiconductor device having a high yield and high reliability and its fabricating method can be provided.

Also, in this illustrative embodiment, the lower electrode has a double-layer structure including the first lower electrode 260 and the second lower electrode 280. Alternatively, as shown in FIG. 1, the lower electrode may include only the first lower electrode 260, and an outer surface of the protruding portion 240a protruding outward which includes upper portions of the adhesion layer 240 and the first lower electrode 260 may be covered directly with the ferroelectric film 360. In this case, when a BiT film is used as the ferroelectric film 360, the adhesion layer 240 is essentially made of a material which does not contain Ti or Ir. For example, the adhesion layer 240 is preferably made of one of titanium aluminum nitride, titanium aluminum oxynitride, ruthenium oxide, and ruthenium, or a multilayer film including one or two or more thereof.

Also, in the case of the structure of FIG. 1, the adhesion layer 240 is interposed between an upper portion of the first lower electrode 260 and the ferroelectric film 360, which is equivalent to an increase in the film thickness of the ferroelectric film 360. Therefore, if the adhesion layer 240 has the same film thickness as that of the ferroelectric film 360, then when both surfaces of the upper portion of the first lower electrode 260 are allowed to contribute to formation of a capacitor, the effect of increasing the charge capacity is halved as compared to when the adhesion layer 240 is not interposed.

Also, in this illustrative embodiment, the adhesion layer 240 is formed at a portion of the first lower electrode 260 which is exposed from the second interlayer insulating film 160 as well. Alternatively, as shown in FIG. 2, the adhesion layer 240 may be provided only at a portion of the first lower electrode 260 which faces the second interlayer insulating film 160.

Also, in this illustrative embodiment, the adhesion layer 240 is formed only on the side surface of the hole 180, but not on the bottom surface. Alternatively, if the adhesion layer 240 is made of a conductive material, the adhesion layer 240 may be provided on the bottom surface of the hole 180 (between the oxygen barrier film 140 and the first lower electrode 260).

Note that platinum (Pt) is used as a noble metal which is a material for the first lower electrode 260, the second lower electrode 280, and the upper electrode 340 in the this illustrative embodiment. Alternatively, as the noble metal, iridium (Ir), ruthenium (Ru), gold (Au), silver (Ag), palladium (Pd), an oxide of rhodium (Rh) or osmium (Os), iridium oxide (IrO₂), ruthenium oxide (RuO₂), silver oxide (Ag₂O) or the like may be used, whereby a similar advantage is achieved. Also, a multilayer structure made of these films may be used. Moreover, iron oxide (Fe₂O₃, Fe₃O₄) may be used.

Also, in this illustrative embodiment, BiT is used as the ferroelectric film 360. The ferroelectric film 360 may be made of any other compound that has a perovskite structure whose general formula is represented by ABO₃, where A and B are different elements, whereby a similar effect can be obtained. Here, the element A is, for example, at least one selected from the group consisting of lead (Pb), barium (Ba), strontium (Sr), calcium (Ca), lanthanum (La), lithium (Li), sodium (Na), potassium (K), magnesium (Mg), and bismuth (Bi). The element B is, for example, at least one selected from the group consisting of titanium (Ti), zirconium (Zr), niobium (Nb), tantalum (Ta), tungsten (W), iron (Fe), nickel (Ni), scandium (Sc), cobalt (Co), hafnium (Hf), magnesium (Mg), and molybdenum (Mo).

Also, in this illustrative embodiment, titanium oxide (TiOₓ) is used as the adhesion layer 240. Alternatively, as a material for the adhesion layer 240, titanium nitride (TiN), titanium aluminum nitride (TiAlN), titanium aluminum oxynitride (TiAlON), titanium nitride (TiN), iridium oxide (IrOx), iridium (Ir), ruthenium oxide (RuOx), or ruthenium (Ru) may be used, whereby a similar advantage can be achieved. Also, a multilayer structure made of these materials may be used. Note that “x” in the general formulas of iridium oxide and ruthenium oxide is a positive real number.

As described above, the semiconductor device and its fabricating method according to the present disclosure can prevent deformation of a noble metal electrode included in a lower electrode to form a three-dimensional cell having a non-defective shape, thereby increasing the charge capacity while keeping the same projected area. In particular, the semiconductor device and its fabricating method according to the present disclosure are useful for a three-dimensional cell having a structure in which a portion of an interlayer insulating film surrounding the three-dimensional cell is etched to expose an outer side surface of a lower electrode of the three-dimensional cell, thereby allowing both side surfaces of the lower electrode to contribute to formation of an amount of charge.

What is claimed is:

1. A semiconductor device comprising:
an interlayer insulating film formed on a semiconductor substrate and having an opening;
an adhesion layer formed on at least a side wall of the opening;
a lower electrode formed on a bottom surface of the opening and at least a side surface of the adhesion layer;
a capacitor insulating film made of a ferroelectric or high-k material formed on the lower electrode; and
an upper electrode formed on the capacitor insulating film,
wherein
the lower electrode, the capacitor insulating film and the upper electrode constitute a capacitor, and the capacitor has a cross-section having a recessed shape in the opening formed in the interlayer insulating film,
the lower electrode has a protruding portion protruding from the opening,
the capacitor insulating film is formed, covering at least the protruding portion of the lower electrode, of the lower electrode and the adhesion layer, and
the upper electrode is formed, covering the capacitor insulating film formed on the protruding portion.

2. The semiconductor device of claim 1, wherein
the adhesion layer is formed, protruding from the opening;
the lower electrode is formed on the side surface of the adhesion layer;
the capacitor insulating film is formed, covering protruding portions protruding from the opening of the lower electrode and the adhesion layer.

3. The semiconductor device of claim 1, wherein
the adhesion layer is formed only on the side wall of the opening,
the protruding portion of the lower electrode protrudes from an upper end of the adhesion layer, and
the capacitor insulating film is formed, directly covering the protruding portion of the lower electrode.

4. The semiconductor device of claim 1, further comprising:
an oxygen barrier film formed between the bottom surface of the opening in the interlayer insulating film and the lower electrode.

5. The semiconductor device of claim 1, further comprising:
a contact plug formed in a lower portion of the opening in the interlayer insulating film and electrically connected to the lower electrode.

6. The semiconductor device of claim 1, wherein
a length of the protruding portion of the lower electrode is smaller than or equal to one third of the sum of the length of the protruding portion of the lower electrode and a length of a portion facing the side wall of the opening of the interlayer insulating film.

7. The semiconductor device of claim 1, wherein
the adhesion layer is made of one of titanium oxide, titanium nitride, titanium aluminum nitride, titanium aluminum oxynitride, iridium oxide, iridium, ruthenium oxide, and ruthenium, or a multilayer film including two or more thereof.

8. The semiconductor device of claim 1, wherein
the lower and upper electrodes are each made of one of platinum, iridium, ruthenium, gold, silver, palladium, an oxide of rhodium or osmium, iridium oxide, ruthenium oxide, iron oxide, and silver oxide, or a multilayer film including two or more thereof.

9. The semiconductor device of claim 1, wherein
the ferroelectric material is a compound having a perovskite structure whose general formula is represented by ABO₃, where A and B are different elements.

10. The semiconductor device of claim 9, wherein
the element A is at least one selected from the group consisting of lead, barium, strontium, calcium, lanthanum, lithium, sodium, potassium, magnesium, and bismuth, and
the element B is at least one selected from the group consisting of titanium, zirconium, niobium, tantalum, tungsten, iron, nickel, scandium, cobalt, hafnium, magnesium, and molybdenum.

11. A semiconductor device comprising:
an interlayer insulating film formed on a semiconductor substrate and having an opening;
an adhesion layer formed on at least a side wall of the opening and having a protruding portion protruding above the interlayer insulating film;
a first lower electrode formed on a bottom surface of the opening and a side surface of the adhesion layer;
a second lower electrode formed on the first lower electrode;
a capacitor insulating film made of a ferroelectric or high-k material formed on the second lower electrode; and
an upper electrode formed on the capacitor insulating film,
wherein
the first lower electrode, the capacitor insulating film and the upper electrode constitute a capacitor, and the capacitor has a cross-section having a recessed shape in the opening formed in the interlayer insulating film,
the second lower electrode is formed, extending from over the first lower electrode to over an outer side surface of the protruding portion of the adhesive layer,
the capacitor insulating film is formed, covering the second lower electrode formed at the protruding portion, and
the upper electrode is formed, covering the capacitor insulating film formed at the protruding portion.

12. The semiconductor device of claim 11, further comprising:
an oxygen barrier film formed between the bottom surface of the opening in the interlayer insulating film and the first lower electrode.

13. The semiconductor device of claim 11, further comprising:
a contact plug formed in a lower portion of the opening in the interlayer insulating film and electrically connected to the first lower electrode.

14. The semiconductor device of claim 11, wherein
a length of the protruding portion of the first lower electrode is smaller than or equal to one third of the sum of the length of the protruding portion of the first lower electrode and a length of a portion facing the side wall of the opening of the interlayer insulating film.

15. The semiconductor device of claim 11, wherein
the adhesion layer is made of one of titanium oxide, titanium nitride, titanium aluminum nitride, titanium aluminum oxynitride, iridium oxide, iridium, ruthenium oxide, and ruthenium, or a multilayer film including two or more thereof.

16. The semiconductor device of claim 11, wherein
the first lower electrode and the upper electrode are each made of one of platinum, iridium, ruthenium, gold, silver, palladium, an oxide of rhodium or osmium, iridium oxide, ruthenium oxide, iron oxide, and silver oxide, or a multilayer film including two or more thereof.

17. The semiconductor device of claim 11, wherein
the second lower electrode is made of one of platinum, iridium, ruthenium, gold, silver, palladium, an oxide of rhodium or osmium, iridium oxide, ruthenium oxide, iron oxide, and silver oxide, or a multilayer film including two or more thereof.

18. The semiconductor device of claim 11, wherein
the ferroelectric material is a compound having a perovskite structure whose general formula is represented by ABO₃, where A and B are different elements.

19. The semiconductor device of claim 18, wherein
the element A is at least one selected from the group consisting of lead, barium, strontium, calcium, lanthanum, lithium, sodium, potassium, magnesium, and bismuth, and
the element B is at least one selected from the group consisting of titanium, zirconium, niobium, tantalum, tungsten, iron, nickel, scandium, cobalt, hafnium, magnesium, and molybdenum.

20. A method for fabricating a semiconductor device comprising the steps of:
(a) forming a first interlayer insulating film on a semiconductor substrate;
(b) forming a contact plug in the first interlayer insulating film, the contact plug being connected to the semiconductor substrate;
(c) forming a second interlayer insulating film on the first interlayer insulating film, the second interlayer insulating film covering the contact plug;
(d) forming an opening in the second interlayer insulating film, the opening exposing the contact plug;
(e) forming an adhesion layer on at least a side wall of the opening;
(f) forming a first lower electrode on a bottom surface of the opening and a side surface of the adhesion layer;
(g) removing an upper portion surrounding the opening of the second interlayer insulating film to allow a portion of the adhesion layer and a portion of the first lower electrode to protrude above the second interlayer insulating film;
(h) forming a second lower electrode extending from along the first lower electrode in the opening to over an outer side surface of the portion protruding above the second interlayer insulating film of the adhesion layer;
(i) forming a capacitor insulating film made of a ferroelectric or high-k material, the capacitor insulating film extending from along the second lower electrode in the opening to over an outer side surface of the second lower electrode at the portion protruding above the second interlayer insulating film of the adhesion layer;
(j) forming an upper electrode extending from along the capacitor insulating film in the opening to over an outer side surface of the capacitor insulating film at the portion protruding above the second interlayer insulating film of the adhesion layer;
(k) forming a third interlayer insulating film on the second interlayer insulating film including the upper electrode; and
(l) after step (k), subjecting the semiconductor substrate to a thermal process under oxidation atmosphere to crystallize the capacitor insulating film,
wherein
the first lower electrode, the second lower electrode, the capacitor insulating film, and the upper electrode constitute a capacitor, and
the capacitor has a cross-section having a recessed shape in the opening formed in the second interlayer insulating film.

21. The method of claim 20, further comprising the step of:
(m) between steps (b) and (c), forming an oxygen barrier film covering the contact plug,
wherein
in step (d), the oxygen barrier film is exposed instead of the contact plug.

22. The method of claim 20, wherein
in step (g), the upper portion surrounding the opening of the second interlayer insulating film is removed so that a length of the portion protruding above the second interlayer insulating film of the adhesion layer and the first lower electrode is smaller than or equal to one third of the sum of the length of the portion protruding above the second interlayer insulating film of the adhesion layer and the first lower electrode and a length of a portion facing the side wall of the opening of the second interlayer insulating film.

23. The method of claim 20, wherein
the adhesion layer is made of one of titanium oxide, titanium nitride, titanium aluminum nitride, titanium aluminum oxynitride, iridium oxide, iridium, ruthenium oxide, and ruthenium, or a multilayer film including two or more thereof.

24. The method of claim 20, wherein
the first and second lower electrodes and the upper electrode are each made of one of platinum, iridium, ruthenium, gold, silver, palladium, an oxide of rhodium or osmium, iridium oxide, ruthenium oxide, iron oxide, and silver oxide, or a multilayer film including two or more thereof.

25. The method of claim 20, wherein
the ferroelectric material is a compound having a perovskite structure whose general formula is represented by ABO₃, where A and B are different elements.

26. The method of claim 25, wherein
the element A is at least one selected from the group consisting of lead, barium, strontium, calcium, lanthanum, lithium, sodium, potassium, magnesium, and bismuth, and
the element B is at least one selected from the group consisting of titanium, zirconium, niobium, tantalum, tungsten, iron, nickel, scandium, cobalt, hafnium, magnesium, and molybdenum.
